(19) United States
(12) Patent Application Publication
(10) Pub. No.: US 2026/0211025 A1
(43) Pub. Date: Jul. 23, 2026

(54) RESISTANCE MEASUREMENT DEVICE

(71) Applicant: LG INNOTEK CO., LTD., Seoul (KR)

(72) Inventor: Dong Keun YOON, Seoul (KR)

(73) Assignee: LG INNOTEK CO., LTD., Seoul (KR)

(21) Appl. No.: 19/139,223

(22) PCT Filed: Dec. 12, 2023
(86) PCT No.: PCT/KR2023/020483

§ 371 Date: Jun. 13, 2025

(30) Foreign Application Priority Data
Dec. 13, 2022 (KR) 10-2022-0174248

(51) Int. Cl. G01R 31/14; H02S 50/10

(52) U.S. Cl. CPC G01R 31/14; H02S 50/10

(57) ABSTRACT

A resistance measurement device according to one embodiment of the present invention comprises: a first resistor unit connected between the (+) terminal of a first channel and a ground; a second resistor unit connected between the (+) terminal of a second channel and the ground; a third resistor unit connected between the (−) terminals of the first and second channels and the ground; a voltage measurement unit which measures the voltage applied across both ends of the first resistor unit, the second resistor unit, or the third resistor unit; and a processing unit which calculates an insulation resistance using the resistance values of the first resistor unit, the second resistor unit, and the third resistor unit, and the voltage value of one of the first resistor unit, the second resistor unit, or the third resistor unit, wherein the first channel and the second channel are connected in parallel.

### TECHNICAL FIELD

The present disclosure relates to a resistance measurement device, and more particularly, to a resistance measurement device, a resistance measurement circuit, and a resistance measurement method for measuring the insulation resistance of channels connected in parallel.

### BACKGROUND ART

As awareness of environmental protection has increased in recent years, interest in methods of generating electricity without emitting pollutants such as carbon dioxide has grown. In particular, power generation systems using solar energy are becoming more widespread as technological advancements have made development and installation costs cheaper.

These solar power generation systems including a plurality of photovoltaic modules in which a plurality of photovoltaic cells are assembled. DC power generated from the plurality of photovoltaic modules is converted into AC power through an inverter and the AC power is usable directly in homes and industrial facilities.

On the other hand, in the case of photovoltaic power generation, there is bound to be a gap in power generation due to the absence of sunlight at night or changes in the weather, when sufficient power generation is not possible. Therefore, to compensate for these shortcomings, photovoltaic power generation systems must be provided with batteries to ensure a stable supply of power.

A home photovoltaic system including a battery may be configured as shown in FIG. 1. The inside of the battery pack may be provided with a battery, a battery management system (BMS), and a DC-DC converter. At this time, when using a plurality of photovoltaic power panels or a plurality of battery packs, the insulation of a plurality of channels connecting them must be maintained to enable stable system operation. There is a need for a technology capable of accurately and quickly detecting whether insulation is maintained.

### DISCLOSURE OF INVENTION

### Technical Problem

The technical problem to be solved by the present disclosure is to provide a resistance measurement device, a resistance measurement circuit, and a resistance measurement method for measuring the insulation resistance of channels connected in parallel.

### Solution to Problem

To solve the technical problems, a resistance measurement device according to an embodiment of the present disclosure includes: a first resistor unit connected between a (+) terminal of a first channel and ground; a second resistor unit connected between a (+) terminal of a second channel and the ground; a third resistor unit connected between a (−) terminal of the first channel and a (−) terminal of the second channel and the ground; a voltage measurement unit configured to measure a voltage applied across the first resistor unit, the second resistor unit, or the third resistor unit; and a processing unit configured to calculate an insulation resistance by using resistance values of the first resistor unit, the second resistor unit, and the third resistor unit and a voltage value of one of the first resistor unit, the second resistor unit, and the third resistor unit, wherein the first channel and the second channel are connected in parallel.

Additionally, the processing unit may be configured to measure the voltages applied across both ends of the first resistor unit, the second resistor unit, and the third resistor unit in a first state where the first resistor unit has a first resistance value, the second resistor unit has a second resistance value, and the third resistor unit has a third resistance value, measure the voltage applied across both ends of the first resistor unit, the second resistor unit, or the third resistor unit in a second state where the first resistor unit has a fourth resistance value, the second resistor unit has a fifth resistance value, or the third resistor unit has a sixth resistance value, and calculate the insulation resistance by using a voltage difference between the voltages applied across both ends of the first resistor unit, the second resistor unit, or the third resistor unit in the first state and the second state.

Additionally, the processing unit may be configured to change a resistance value of a resistor unit having a largest voltage across both ends measured in the first state, and calculate the insulation resistance by using the voltage difference, the voltage of the resistor unit whose resistance value has been changed in the first state, the first resistance value, the second resistance value, the third resistance value, and the changed resistance value.

Additionally, the processing unit may be configured to compare the insulation resistance with a reference insulation resistance to determine whether the insulation resistance is within a normal range.

Additionally, the insulation resistance may be a total parallel insulation resistance of the first channel and the second channel.

Additionally, the first resistor unit may include a first resistor, a second resistor connected in parallel to the first resistor, and a first switch connected in series to the second resistor, the second resistor unit may include a third resistor, a fourth resistor connected in parallel to the third resistor, and a second switch connected in series to the fourth resistor, and the third resistor unit may include a fifth resistor, a sixth resistor connected in parallel to the fifth resistor, and a third switch connected in series to the sixth resistor.

Additionally, the second resistor, the fourth resistor, and the sixth resistor may have a same resistance value.

Additionally, the resistance measurement device may include a fourth switch configured to connect the first resistor unit, the second resistor unit, and the third resistor unit to ground.

To solve the technical problems, a resistance measurement circuit according to an embodiment of the present disclosure includes: a plurality of (+) terminal resistor units connected between a (+) terminal of each of a plurality of channels and ground; one (−) terminal resistor unit connected between a node to which (−) terminals of the plurality of channels are connected and the ground; and a voltage measurement unit configured to measure a voltage applied across both ends of at least one (+) terminal resistor unit among the plurality of (+) terminal resistor units, or the (−) terminal resistor unit, wherein the plurality of channels are connected in parallel.

Additionally, the resistance measurement device may include a processing unit configured to calculate a total parallel insulation resistance of the plurality of channels by using the resistance value of each of the plurality of (+) terminal resistor units, the resistance value of the (−) terminal resistor unit, and one of the voltage values among the at least one (+) terminal resistor unit and the (−) terminal resistor unit.

Additionally, the processing unit may change the resistance value of the resistor unit having the largest magnitude of the voltage across both ends measured in the first state, and may calculate the total parallel insulation resistance by using the voltage difference measured in the second state where the resistance value is changed, the voltage of the resistor unit whose resistance value is changed in the first state, the resistance value of each of the plurality of (+) terminal resistor units in the first state, the resistance value of the (−) terminal resistor unit in the first state, and the changed resistance value.

To solve the technical problems, an embodiment of the present disclosure includes: turning on a switch that connects, to ground. a resistance measurement circuit connected to a plurality of channels connected in parallel; measuring a voltage between a (+) terminal of each of the plurality of channels and the ground and a voltage between a node to which (−) terminals of the plurality of channels are connected and the ground in a first state; changing a resistance value of one of a plurality of (+) terminal resistor units between the (+) terminals of the plurality of channels and the ground and s (−) terminal resistor unit between a node to which the (−) terminals of the plurality of channels are connected and the ground; and calculating a total parallel insulation resistance of the plurality of channels by using the resistance value of each of the plurality of (+) terminal resistor units, the resistance value of the (−) terminal resistor unit, and the voltage value of one of the voltage values of at least one (+) terminal resistor unit and the (−) terminal resistor unit.

Additionally, the changing of the resistance value may include changing the resistance value by connecting a resistor having a preset resistance value in parallel to the resistor unit having the largest magnitude of the voltage measured at both ends in the first state.

Additionally, the calculating of the total parallel insulation resistance of the plurality of channels may include calculating the total parallel insulation resistance by using the voltage value in the second state where the resistance value of the resistor unit whose resistance value has been changed is changed, the resistance value of the resistor unit whose resistance value has been changed in the first state, the resistance value of each of the plurality of (+) terminal resistor units in the first state, the resistance value of the (−) terminal resistor unit in the first state, and the resistance value of the resistors connected in parallel.

Additionally, comparing the total parallel insulation resistance with the reference insulation resistance to determine whether the total parallel insulation resistance is within a normal range may be included.

### Advantageous Effects of Invention

According to embodiments of the present disclosure, even when a plurality of channels are connected in parallel for a photovoltaic power generation panel array or a battery pack, the total parallel insulation resistance may be calculated, thereby detecting a single or multiple fault states. Additionally, it may be applied under conditions where single or multiple channels are connected in parallel, regardless of the number of channels. It may be used not only for photovoltaic power systems but also for measuring the insulation resistance of batteries, and thus, expandability is excellent. Furthermore, insulation resistance measurement under parallel connection conditions is possible by using a simple measurement circuit, the number of parts for relay or switch elements may be reduced, and a separate power source for initially driving the relay or switch is not required. In other words, accurate insulation resistance values may be calculated with just a simple sequence, which helps ensure product competitiveness.

### BRIEF DESCRIPTION OF DRAWINGS

FIG. 1 is a diagram for describing a photovoltaic power generation system to which a resistance measurement device according to an embodiment of the present disclosure is applied.

FIG. 2 is a block diagram of a resistance measurement device according to an embodiment of the present disclosure.

FIGS. 3 to 5 are diagrams for describing a resistance measurement device according to an embodiment of the present disclosure.

FIG. 6 is a block diagram of a resistance measurement circuit according to an embodiment of the present disclosure.

FIG. 7 is a flowchart of a resistance measurement method according to an embodiment of the present disclosure.

FIG. 8 is a flowchart of a resistance measurement method according to an embodiment of the present disclosure.

### MODE FOR THE INVENTION

Hereinafter, preferred embodiments of the present disclosure will be described in detail with reference to the accompanying drawings.

However, the technical concept of the present disclosure is not limited to some embodiments described herein and may be implemented in various different forms, and one or more of components among embodiments may be selectively combined or substituted for use within the scope of the technical concept of the present disclosure.

In addition, unless defined otherwise, the terms (including technical and scientific terms) as used in embodiments of the present disclosure have the same meaning as commonly understood by those of ordinary skill in the art. The meaning of commonly used terms, such as terms defined in the dictionary, may be interpreted considering the context of the relevant technology.

In addition, the terms used in embodiments of the present disclosure are for the purpose of describing the embodiments and are not intended to limit the present disclosure.

In the present specification, the singular forms may also include the plural forms unless specifically stated otherwise in the phrase, and the expression “at least one (or one or more) of A, B, and C” may mean including one or more of all combinations of A, B, and C.

Additionally, in describing components of embodiments of the present disclosure, terms such as first, second, A, B, (A), (B), etc. may be used. These terms are only intended to distinguish one component from another and are not intended to limit the nature, order, or sequence of the component.

When a component is described as being ‘connected’, ‘coupled’, or ‘linked’ to another component, it may include not only a case where the component is ‘connected’, ‘coupled’, or ‘linked’ directly to the other component, but also a case where the component is ‘connected’, ‘coupled’, or ‘linked’ by another component between the component and the other component.

Additionally, when a component is described as being formed or arranged “above” or “below” each component, the terms “above” or “below” includes not only a case where the two components are in direct contact with each other, but also a case where one or more other components are formed or arranged between the two components. Additionally, when expressed as “above” or “below”, it may include the meaning of not only an upward direction but also a downward direction based on one component.

Modifications of the present embodiments may include some configurations of the respective embodiment and some configurations of other embodiments together. That is, a the modifications may include one embodiment among various embodiments, but some components may be omitted and some components of the corresponding other embodiment may be included. Or, vice versa. The features, structures, effects, etc. to be described in the embodiments are included in at least one embodiment, and are not necessarily limited to only one embodiment. Furthermore, the features, structures, effects, etc. described in each embodiment may be combined or modified and implemented in other embodiments by those of ordinary skill in the art. Therefore, the descriptions related to these combinations and modifications should be interpreted as falling within the scope of the embodiment.

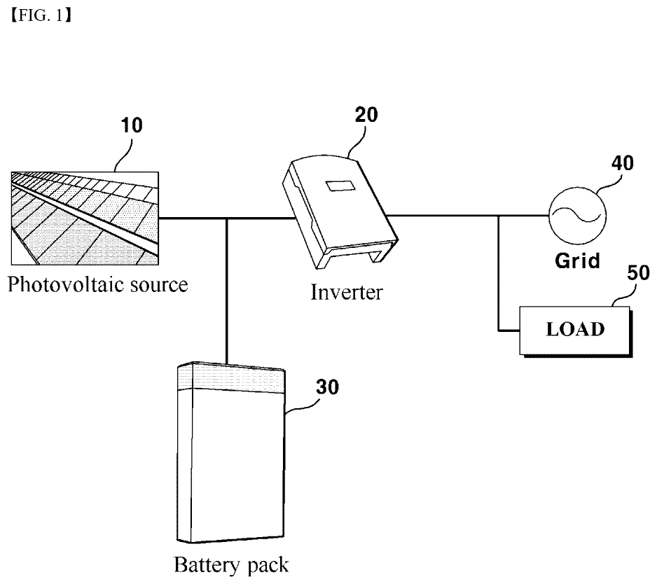

FIG. 1 is a diagram for describing a photovoltaic power generation system to which a resistance measurement device according to an embodiment of the present disclosure is applied.

As illustrated in FIG. 1, the photovoltaic power generation system may include a photovoltaic power source 10, an inverter 20, a battery pack 30, and a load 50. However, it will be understood by those of ordinary skill in the art that other general components may be included in the photovoltaic power generation system in addition to the components illustrated in FIG. 1. For example, the photovoltaic power system may further include a grid 40. Alternatively, it will be understood by those of ordinary skill in the art that, in other embodiments, some of the components illustrated in FIG. 1 may be omitted.

The photovoltaic power source 10 may include a plurality of photovoltaic modules in which photovoltaic cells are assembled, and the photovoltaic cell in which a P-type semiconductor and an N-type semiconductor are bonded generates electricity by using light. Specifically, when light is irradiated onto the photovoltaic cell, electrons and holes are generated therein. The generated charges move to a P pole and an N pole, and this action generates a potential difference between the P pole and the N pole. At this time, when a load is connected to the photovoltaic cell, current flows. Here, the photovoltaic cell refers to the smallest unit that generates electricity, and photovoltaic cells are assembled to together to form a battery module. The battery modules may form an array connected in series/parallel to form the photovoltaic power source 10.

The inverter 20 may convert direct current (DC) power generated from the photovoltaic power source 10 by the photoelectric effect into alternating current (AC) power so as to supply power to the grid 40 or the load 50. Here, the grid 40 may refer to a grid for transmitting and distributing power generated from the photovoltaic power generation system. On the other hand, the amount of power generated from the photovoltaic power source 10 continues to change due to time factors such as sunrise and sunset or external factors such as weather. Therefore, the inverter 20 controls the voltage generated from the photovoltaic power source 10 to find the maximum power and supply the maximum power to the grid 40. At this time, when the power for operating the inverter is lower than the output power of the inverter, the inverter 20 may consume power from the grid 40 in reverse. Of course, in this case, the inverter may block the power flowing into the grid 40 to prevent the power from being reversed. Accordingly, various optimizer control methods are applied to the photovoltaic power generation system so as to enable the operation of the inverter 20 described above to be performed more efficiently and to extract maximum power from the photovoltaic power source 10. Typical maximum power point tracking (MPP) methods for the photovoltaic power sources 10 include a perturbation and observation (PO) method, an incremental conductance (IC) control method, and a constant voltage (CV) control method. Here, the PO method is a method of periodically measuring the voltage and current of the photovoltaic power source 10 to calculate power and then tracking the MPP by using the power value. The IC control method is a method of measuring the voltage and current generated from the photovoltaic power source 10 and performing control so that the rate of change in power for a change in a terminal voltage operating point of an array becomes ‘0’. The CV control method is a method of controlling the photovoltaic power source 10 to a constant reference voltage (REF V) regardless of an operating voltage or power of an array. Depending on each optimizer control method, the power source input from the photovoltaic power source 10 to the inverter may operate as a voltage source or a current source.

The load 50 may refer to a product that uses an electric form used in real life. For example, the inverter 20 may obtain AC power of a desired voltage and frequency through an appropriate conversion method, a switching element, or a control circuit, and may supply electricity to home appliances in general households or mechanical products in industrial facilities. Additionally, in the case of photovoltaic power generation, there is bound to be a gap in power generation due to the absence of sunlight at night or changes in the weather, when sufficient power generation is not possible. Therefore, to compensate for these shortcomings, photovoltaic power generation systems must be provided with batteries to ensure a stable supply of power.

The battery pack 30 may include at least one of a DC-DC converter, a battery, a battery management system (BMS), and a battery control circuit. The battery may include a lithium-ion battery or a nickel-metal hydride battery, but the present disclosure is not necessarily limited to this configuration, and the battery may refer to a battery that is usable semi-permanently through charging. The DC-DC converter is a device that converts DC power generated through the photovoltaic power source 10 into DC power suitable for the battery, or converts battery power into power suitable for the grid. Generally, the DC-DC converter may convert power by converting DC power into AC power and then converting AC power back into DC power. The BMS may provide a misuse protection function of a cell constituting the battery and a function to balance between unit cells, measure a state of charge (SOC), maintain temperature, or monitor the system. Therefore, based on a sensor that measures the state of the cell and a function of receiving the measurement value of the sensor and transmitting the measurement value to the control system of the application product, a circuit that generates an abnormal signal and blocks or opens the power circuit between cells when the temperature and charging state of the system exceed a set value may be constructed and controlled.

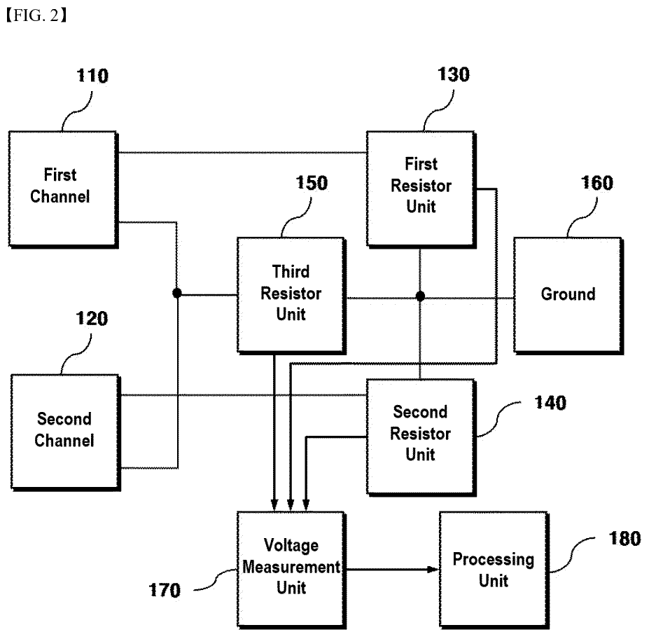

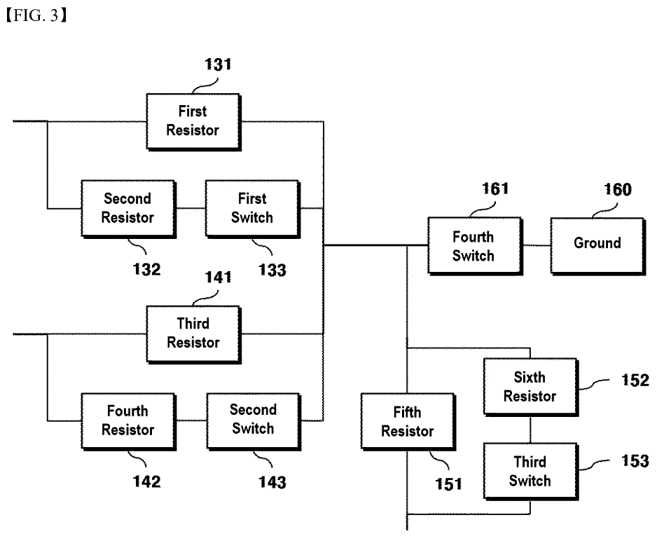

FIG. 2 is a block diagram of a resistance measurement device according to an embodiment of the present disclosure, and FIGS. 3 to 5 are diagrams for describing a resistance measurement device according to an embodiment of the present disclosure.

The resistance measurement device according to an embodiment of the present disclosure detects an insulation resistance for one or more channels. Here, one or more photovoltaic power panels or battery packs may be connected to the channel whose insulation resistance is to be detected. By detecting the insulation resistance, it is possible to determine whether insulation is maintained in the power output from the photovoltaic power panels or battery packs. The photovoltaic power panels or battery packs that are determined to be safe because insulation is maintained may be connected to devices or circuits that are intended to supply power output therefrom. That is, an insulation resistance device according to an embodiment of the present disclosure may be used to check whether the insulation resistance is maintained above a reference value before connecting the photovoltaic power generation panel or the battery pack. Here, it is obvious that the device connected to the channel measuring the insulation resistance may include various devices requiring insulation, as well as the photovoltaic power panels or the battery packs.

The resistance measurement device according to an embodiment of the present disclosure may measure insulation resistance for a plurality of channels. The plurality of channels may be connected in parallel. When the plurality of channels are connected in parallel, safety may be determined by measuring the insulation resistance of the connected channels. Expandability is high because the insulation resistance may be measured quickly and accurately even when the number of channels connected in parallel increases. Hereinafter, an embodiment in which two channels are connected in parallel is described. It is obvious that the present disclosure may be applied to one channel or three or more channels.

The resistance measurement device according to an embodiment of the present disclosure may include a first resistor unit 130, a second resistor unit 140, a third resistor unit 150, a voltage measurement unit 170, and a processing unit 180, and may include one or more switches and one or more memories.

A first channel 110 and a second channel 120 are connected in parallel, and a photovoltaic power generation panel array or a battery pack may be connected to the first channel 110 and the second channel 120. In order to measure an insulation resistance, before the power supplied through the first channel 110 and the second channel 120 is connected to the device to which the power is to be supplied, the first resistor unit 130 is connected between the (+) terminal of the first channel 110 and ground 160, the second resistor unit 140 is connected between the (+) terminal of the second channel 120 and the ground 160, and the third resistor unit 150 is connected between the (−) terminal of the first channel 110 and the (−) terminal of the second channel 120 and the ground 160. The first resistor unit 130 and the second resistor unit 140 are each used to measure the (+) terminal voltage of the channel, and the third resistor unit 150 may be used to measure the (−) terminal voltages of the entire channels.

The first resistor unit 130 includes a first resistor 131, a second resistor 132 connected in parallel to the first resistor 131, and a first switch 133 connected in series to the second resistor 132. In the first resistor unit 130, when the first switch 133 is turned off, only the first resistor 131 is connected, and when the first switch 133 is turned on, the first resistor 131 and the second resistor 132 are connected in parallel. Here, the first resistor 131 may have a first resistance value, and the first resistor 131 and the second resistor 132 connected in parallel may have a fourth resistance value. When connected in parallel, the resistance value decreases, and thus, the fourth resistance value may be less than the first resistance value. The resistance value of the second resistor 132 may be the same as the first resistance value. Alternatively, it is obvious that the resistance value of the second resistor 132 may be greater or less than the first resistance value.

The second resistor unit 140 includes a third resistor 141, a fourth resistor 142 connected in parallel to the third resistor 141, and a second switch 143 connected in series to the fourth resistor 142. In the second resistor unit 140, when the second switch 143 is turned off, only the third resistor 141 is connected, and when the second switch 143 is turned on, the third resistor 141 and the fourth resistor 142 are connected in parallel. Here, the third resistor 141 may have a second resistance value, and the third resistor 141 and the fourth resistor 142 connected in parallel may have a fifth resistance value. When connected in parallel, the resistance value decreases, and thus, the fifth resistance value may be less than the second resistance value. The resistance value of the fourth resistor 142 may be the same as the second resistance value. Alternatively, it is obvious that the resistance value of the fourth resistor 142 may be greater or less than the second resistance value.

The third resistor unit 150 includes a fifth resistor 151, a sixth resistor 152 connected in parallel to the fifth resistor 151, and a third switch 153 connected in series to the sixth resistor 152. In the third resistor unit 150, when the third switch 153 is turned off, only the fifth resistor 151 is connected, and when the third switch 153 is turned on, the fifth resistor 151 and the sixth resistor 152 are connected in parallel. Here, the fifth resistor 151 may have a third resistance value, and the fifth resistor 151 and the sixth resistor 152 connected in parallel may have a sixth resistance value. When connected in parallel, the resistance value decreases, and thus, the sixth resistance value may be less than the third resistance value. The resistance value of the sixth resistor 152 may be the same as the third resistance value. Alternatively, it is obvious that the resistance value of the sixth resistor 152 may be greater or less than the third resistance value.

Here, the second resistor, the fourth resistor, and the sixth resistor may have the same resistance value. When the switch in each resistor unit is turned on and two resistors are connected in parallel, the resistance values of the additional resistors may be the same as each other. In this manner, even when the resistance value of any resistor unit changes, the value of the additional resistor used to calculate the resistance value remains the same, making insulation resistance measurement easier.

A fourth switch 161 that connects the first resistor unit 130, the second resistor unit 140, and the third resistor unit 150 to the ground 160 may be included. The fourth switch 161 that connects the respective resistor units to the ground 160 may be turned on so as to measure an insulation resistance. That is, when connecting the initial channel that requires insulation resistance measurement, the fourth switch 161 may be turned on to connect the first resistor unit 130, the second resistor unit 140, and the third resistor unit 150 to the ground 160. When the fourth switch 161 is turned off, the connection between the first resistor unit 130, the second resistor unit 140, and the third resistor unit 150 and the ground 160 is cut off, and thus, the power supply circuit is not affected.

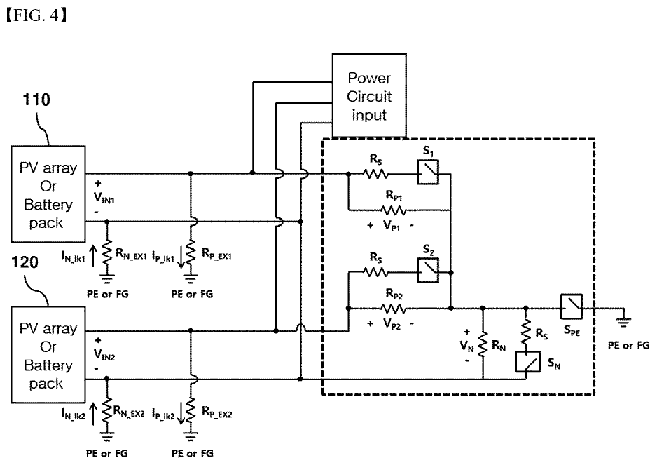

As shown in FIG. 4, the first resistor unit 130 may include a first resistor R_P1, a second resistor R_S, and a first switch S1, and may be connected between a V_IN1 (+) terminal of the first channel 110 and ground PE or FG. The second resistor unit 140 may include a third resistor R_P2, a fourth resistor R_S, and a second switch S2, and may be connected between a V_IN2 (+) terminal of the second channel 120 and the ground PE or FG. The third resistor unit 150 may include a fifth resistor R_N, a sixth resistor R_S, and a third switch S_N, and may be connected between a V_IN1 (−) terminal of the first channel 110 and a V_IN1 (−) terminal of the second channel 120 and the ground PE or FG.

The ground 160 may be protective earth (PE) or frame ground (FG). Here, the PE may be connected to ground GND or to a safety conductor. The FG is the position with the lowest potential of the device and may be connected to a housing of the device. For example, it may be grounded by being connected to a casing of the battery pack, i.e., a chassis of the battery pack. The first channel 110 and the second channel 120 and the ground 160 are designed to be insulated from each other, and thus, an insulation resistance is formed between the first channel 110 and the second channel 120 and the ground 160.

The first switch 133, the second switch 143, the third switch 153, and the fourth switch 161 may include various types of switching elements such as a relay and a semiconductor switching element (MOSFET).

The voltage measurement unit 170 measures the voltages of the first resistor unit 130, the second resistor unit 140, or the third resistor unit 150. The voltage measurement unit 170 may measure the voltages applied across both ends of the first resistor unit 130, the second resistor unit 140, or the third resistor unit 150. The voltage measured by the voltage measurement unit 170 may be stored in a memory.

The processing unit 180 calculates the insulation resistance by using the resistance values of the first resistor unit 130, the second resistor unit 140, and the third resistor unit 150 and one of the voltage values of the first resistor unit 130, the second resistor unit 140, and the third resistor unit 150. In order to measure the insulation resistance formed between the first channel 110 and the second channel 120 and the ground 160, the processing unit 180 calculates the insulation resistance by using the resistance value and the voltage value of each resistor unit. Here, the insulation resistance may be the total parallel insulation resistance of the first channel 110 and the second channel 120. As described above, the insulation resistance is formed between the first channel 110 and the second channel 120 and the ground 160. At this time, the insulation resistance may be formed as insulation resistance between the (+) terminal of the first channel 110 and the ground 160, insulation resistance between the (−) terminal of the first channel 110 and the ground 160, insulation resistance between the (+) terminal of the second channel 120 and the ground 160, and insulation resistance between the (−) terminal of the second channel 120 and the ground 160.

As shown in FIG. 4, the insulation resistance may be formed as an insulation resistance R_P,EX1 between the V_IN1 (+) terminal of the first channel 110 and the ground, an insulation resistance R_N,EX1 between the V_IN1 (−) terminal of the first channel 110 and the ground, an insulation resistance R_P,EX2 between the V_IN2 (+) terminal of the second channel 120 and the ground, and an insulation resistance R_N,EX2 between the V_IN2 (−) terminal of the second channel 120 and the ground.

At this time, all insulation resistances must be maintained above a reference insulation resistance. The reference insulation resistance is the minimum insulation resistance that must be maintained for safety. When even one of the insulation resistances is lower than the reference insulation resistance, it is determined that a fault such as insulation breakdown has occurred, and it is necessary to stop the operation of the system for the safety purpose. The processing unit 180 calculates the insulation resistance by using the resistance value and the voltage value of each resistor unit so as to quickly and accurately determine the insulation resistance.

The four insulation resistances described above are formed in the form that is connected in parallel. Accordingly, by calculating the total parallel insulation resistance, it is possible to check whether the insulation is well maintained. When the plurality of resistors are connected in parallel, the total parallel resistance is less than the smallest resistance value of the respective resistors connected in parallel. By using this point, the total parallel insulation resistance may be calculated, and it is determined whether the calculated total parallel insulation resistance is higher than the reference insulation resistance. Accordingly, it is possible to quickly determine whether the insulation is maintained without calculating individual insulation resistance. When the total parallel insulation resistance is higher than the reference insulation resistance, it means that the individual insulation resistance is also higher than the reference insulation resistance, and thus, it may be determined that it is operating normally.

In order to calculate the total parallel insulation resistance, the processing unit 180 may measure the resistance value and the voltage value in two states and calculate the insulation resistance by applying a voltage distribution formula in each state.

First, the processing unit 180 may measure the voltages applied across both ends of the first resistor unit 130, the second resistor unit 140, and the third resistor unit 150 in a first state in which the first resistor unit 130 has a first resistance value, the second resistor unit 140 has a second resistance value, and the third resistor unit 150 has a third resistance value.

A state where the fourth switch 161 is turned on so that the first resistor unit 130, the second resistor unit 140, and the third resistor unit 150 are connected to the ground and the first switch 133, the second switch 143, and the third switch 153 are turned off so that the first resistor unit 130 has a first resistance value, the second resistor unit 140 has a second resistance value, and the third resistor unit 150 has a third resistance value is the first state. In the first state, the voltages applied across both ends of the first resistor unit 130, the second resistor unit 140, and the third resistor unit 150 are measured.

Thereafter, in a second state where the first resistor unit 130 has a fourth resistance value, the second resistor unit 140 has a fifth resistance value, or the third resistor unit 150 has a sixth resistance value, the voltages applied across both ends of the first resistor unit 130, the second resistor unit 140, or the third resistor unit 150 are measured.

By changing the resistance value of at least one of the first resistor unit 130, the second resistor unit 140, and the third resistor unit 150, the state is changed to the second state different from the first state. In the second state, the voltages applied across both ends of the first resistor unit 130, the second resistor unit 140, or the third resistor unit 150 may be measured.

At this time, the insulation resistance may be calculated by using the voltage difference between the voltages applied across both ends of the first resistor unit 130, the second resistor unit 140, or the third resistor unit 150 in the first state and the second state. The total parallel insulation resistance may be calculated by using the respective resistance values and voltage values in the first state and the second state, which are different states.

When changing to the second state, the processing unit 180 may change the resistance value of the resistor unit having the largest magnitude of the voltage across both ends measured in the first state, and may calculate the insulation resistance by using the voltage difference, the voltage of the resistor unit whose resistance value has been changed in the first state, the first resistance value, the second resistance value, the third resistance value, and the changed resistance value. Fast calculation is possible by changing only the resistance value of the resistor unit with the largest voltage measured at both ends in the first state, and the voltage difference may be increased by changing the value with a large voltage magnitude. Accordingly, an error in calculating the insulation resistance may be reduced.

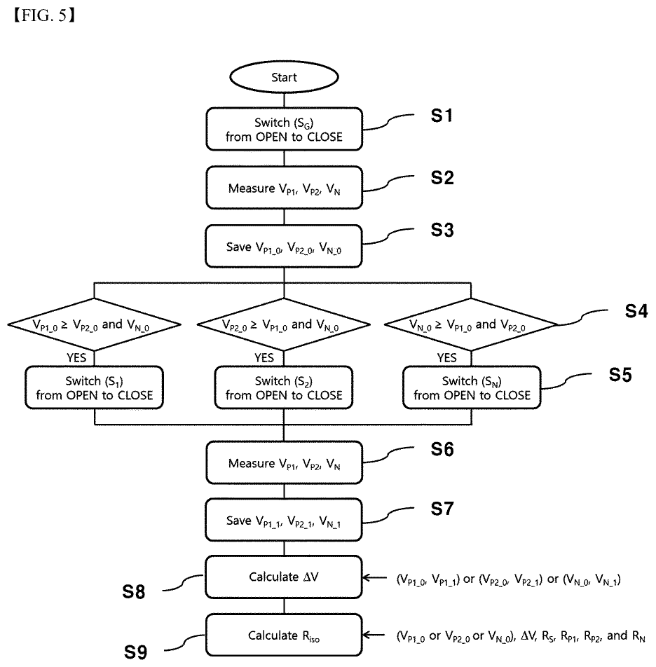

The processing unit 180 may measure the insulation resistance in the same manner as in FIG. 5. First, the switch or the relay that connects the first resistor unit 130, the second resistor unit 140, and the third resistor unit 150 to the ground PE or FG is changed from an open state to a closed state (S1). In the first state, the positive voltages V_P1 and V_P2 and the negative voltage V_N of each channel are measured (S2). The measured values V_P1_0, V_P2_0, and V_N_0 are stored (S3). By comparing the respective measured voltages, the highest voltage is selected from the measured voltages (S4) and the switch of the channel where the corresponding voltage has been measured is changed from an open state to a closed state (S5). Thereafter, once again in the second state, the positive voltages V_P1 and V_P2 and the negative voltage V_N of each channel are measured (S6), and the measured values V_P1_1, V_P2_1, and V_N_1 are stored (S7). The difference V between the voltages measured in the first state and the second state is calculated (S8). Here, V may be calculated as follows.

$$V = V\_P1 \_ 1 - V\_P1 \_ 0 \qquad [ 70 ]$$

$$V = V\_P2 \_ 1 - V\_P2 \_ 0 \qquad [ 71 ]$$

$$V = V\_N \_ 0 - V\_N \_ 1 \qquad [ 72 ]$$

Thereafter, the total parallel resistance value R_ISO of the insulation resistors is calculated by using the resistance values of the measurement circuit, the initially measured voltage values VP1_0, VP2_0, and VN_0, and V (S9). The total parallel resistance value may be used to determine the insulation resistance results of the PV array or the battery pack connected to the channel. That is, when a fault occurs due to insulation breakdown, detection is possible.

The total parallel resistance value R_ISO may be calculated by using the resistance values and the voltage values of the first state and the second state. In the first state and the second state, the difference in the equations according to V=V_P1_1-V_P1_0 occurs at the node between the first resistor unit 130, the second resistor unit 140, and the third resistor unit 150, and the total parallel resistance value R_ISO may be calculated from the difference in the equations of the first state and the second state. The total parallel resistance value R_ISO derived from this is equal to the total parallel resistance value of the values obtained by multiplying the ratio of V according to the voltage of the resistor unit having the largest voltage in the first state by the first resistor 131, the second resistor 132, the third resistor 141, the fifth resistor 151, and the second resistor 132. That is, the total parallel insulation resistance may be calculated by using the voltages of the first state and the second state of the first resistor 131, the second resistor 132, the third resistor 141, the fifth resistor 151, and the resistor unit having the largest voltage in the first state.

The processing unit 180 may compare the calculated insulation resistance with the reference insulation resistance to determine whether the insulation resistance is within a normal range. The calculated insulation resistance may be the total parallel insulation resistance, and when the total parallel insulation resistance is greater than the reference insulation resistance, it may be confirmed that each insulation resistance is greater than the reference insulation resistance, and the insulation is maintained within the normal range.

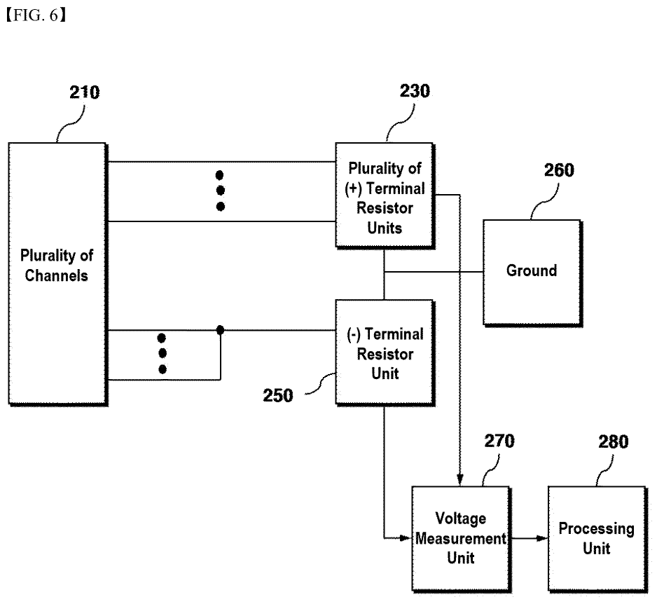

FIG. 6 is a block diagram of a resistance measurement circuit according to an embodiment of the present disclosure. The detailed description of the resistance measurement circuit of FIG. 6 according to an embodiment of the present disclosure corresponds to the detailed description of the resistance measurement device of FIGS. 1 to 5, and thus any redundant description thereof is omitted.

The resistance measurement circuit according to an embodiment of the present disclosure includes a plurality of (+) terminal resistor units 230 connected between (+) terminals of a plurality of channels 210 and ground 260, one (−) terminal resistor unit 250 connected between a node to which the (−) terminals of the plurality of channels are connected and the ground 260, and at least one (+) terminal resistor unit among the plurality of (+) terminal resistor units 230, or a voltage measurement unit 270 measuring the a voltage applied across both ends of the (−) terminal resistor unit 250. The plurality of channels 210 are connected in parallel.

Here, the resistance measurement circuit according to an embodiment of the present disclosure includes a processing unit 280 that calculates the total parallel insulation resistance of the plurality of channels by using the resistance value of each of the plurality of (+) terminal resistor units, the resistance value of the (−) terminal resistor unit, and one of the voltage values among the at least one (+) terminal resistor unit and the (−) terminal resistor unit.

Additionally, the processing unit 280 may change the resistance value of the resistor unit having the largest magnitude of the voltage across both ends measured in the first state, and may calculate the total parallel insulation resistance by using the voltage difference measured in the second state where the resistance value is changed, the voltage of the resistor unit whose resistance value is changed in the first state, the resistance value of each of the plurality of (+) terminal resistor units in the first state, the resistance value of the (−) terminal resistor unit in the first state, and the changed resistance value.

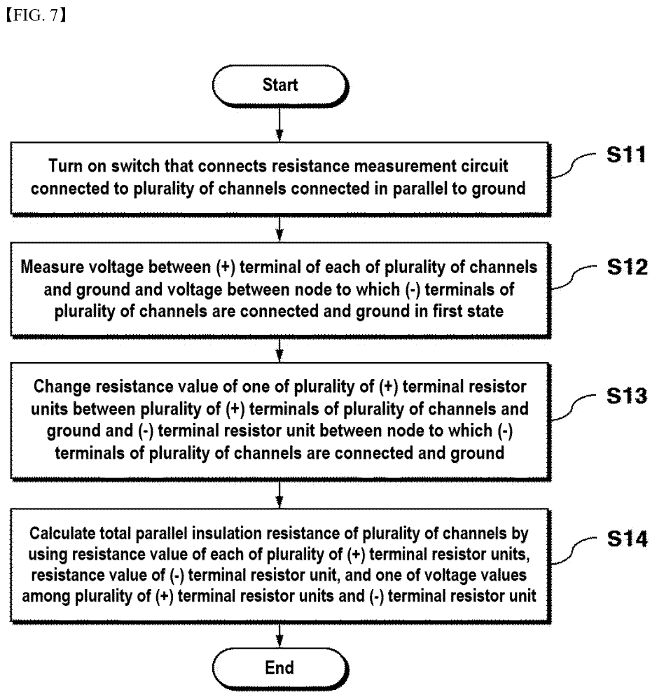

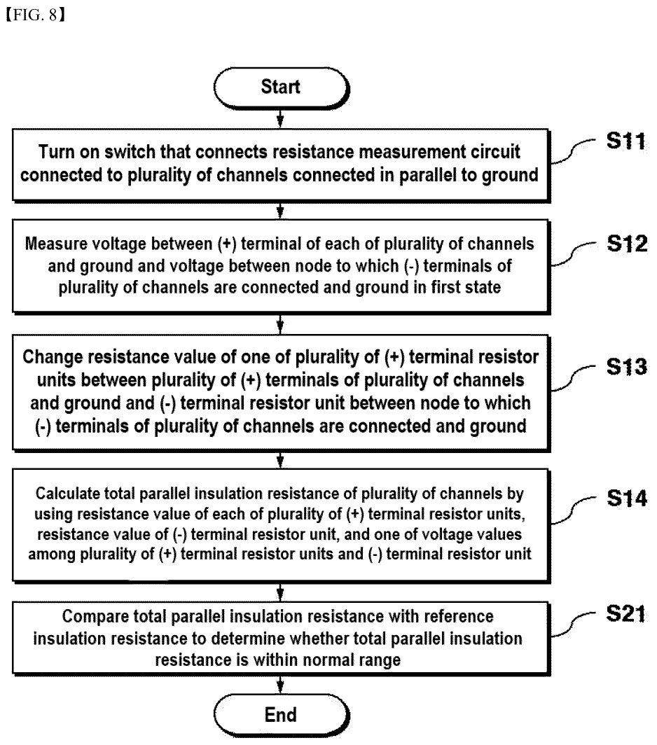

FIG. 7 is a flowchart of a resistance measurement method according to an embodiment of the present disclosure, and FIG. 8 is a flowchart of a resistance measurement method according to an embodiment of the present disclosure. The detailed description of each operation in FIGS. 7 and 8 corresponds to the detailed description of the resistance measurement device of FIGS. 1 to 5 and the insulation resistance detection circuit of FIG. 6, and thus any redundant description thereof is briefly given below.

In operation S11, in order to measure insulation resistances of a plurality of channels, a switch that connects a resistance measurement circuit connected to a plurality of channels connected in parallel to ground is turned on. Here, the plurality of channels may be connected to a plurality of photovoltaic power generation panel arrays or a plurality of battery packs.

Thereafter, in operation S12, a voltage between the (+) terminal of each of the plurality of channels and the ground and a voltage between a node to which the (−) terminals of the plurality of channels are connected and the ground are measured in a first state. In operation S13, a resistance value of one of a plurality of resistor units between the plurality of (+) terminals of the plurality of channels and the ground and a (−) terminal resistor unit between a node to which the (−) terminals of the plurality of channels are connected and the ground is changed. Here, in changing the resistance value, the resistance value may be changed by connecting a resistor having a preset resistance value in parallel to the resistor unit having the largest magnitude of the voltage measured at both ends in the first state.

Thereafter, in operation S14, the total parallel insulation resistance of the plurality of channels is calculated by using the resistance value of each of the plurality of (+) terminal resistor units, the resistance value of the (−) terminal resistor unit, and one of the voltage values among the plurality of (+) terminal resistor units and the (−) terminal resistor unit. Here, the total parallel insulation resistance may be calculated by using the voltage value of the resistor unit whose resistance value has been changed in the second state where the resistance value is changed, the voltage value of the resistor unit whose resistance value has been changed in the first state, the resistance value of each of the plurality of (+) terminal resistor units in the first state, the resistance value of the (−) terminal resistor unit in the first state, and the resistance value of the resistors connected in parallel.

Additionally, in operation S21, the total parallel insulation resistance may be compared with the reference insulation resistance to determine whether the total parallel insulation resistance is within a normal range.

On the other hand, the embodiments of the present disclosure may be implemented as computer-readable code on a computer-readable recording medium. The computer-readable recording medium includes any type of recording device that stores data that can be read by a computer system.

Examples of the computer-readable recording medium include ROM, RAM, CD-ROM, magnetic tape, floppy disks, optical data storage devices, etc., and furthermore, the computer-readable recording medium may be distributed across network-connected computer systems so that computer-readable code may be stored and executed in a distributed manner. Functional programs, code, and code segments for implementing the present disclosure may be easily inferred by programmers in the technical field to which the present disclosure belongs.

Those of ordinary skill in the art will understand that the present disclosure may be implemented in modified forms without departing from the essential features of the present disclosure. Therefore, the disclosed methods should be considered in an illustrative sense rather than a restrictive sense. The scope of the present disclosure is indicated in the claims rather than the foregoing description, and all differences within the scope equivalent thereto should be construed as falling within the present disclosure.

1. A resistance measurement device comprising:
a first resistor unit connected between a (+) terminal of a first channel and ground;
a second resistor unit connected between a (+) terminal of a second channel and the ground;
a third resistor unit connected between a (−) terminal of the first channel, a (−) terminal of the second channel, and the ground;
a voltage measurement unit configured to measure a voltage applied across the first resistor unit, the second resistor unit, or the third resistor unit; and
a processing unit configured to calculate an insulation resistance by using resistance values of the first resistor unit, the second resistor unit, and the third resistor unit and a voltage value of one of the first resistor unit, the second resistor unit, and the third resistor unit, wherein the first channel and the second channel are connected in parallel.

2. The resistance measurement device of claim 1, wherein the processing unit is configured to:
measure voltages applied across both ends of the first resistor unit, the second resistor unit, and the third resistor unit in a first state where the first resistor unit has a first resistance value, the second resistor unit has a second resistance value, and the third resistor unit has a third resistance value;
measure voltage applied across both ends of the first resistor unit, the second resistor unit, or the third resistor unit in a second state where the first resistor unit has a fourth resistance value, the second resistor unit has a fifth resistance value, or the third resistor unit has a sixth resistance value; and
calculate the insulation resistance by using a voltage difference between the voltages applied across both ends of the first resistor unit, the second resistor unit, or the third resistor unit in the first state and the second state.

3. The resistance measurement device of claim 2, wherein the processing unit is configured to:
change a resistance value of a resistor unit having a largest voltage across both ends measured in the first state; and
calculate the insulation resistance by using the voltage difference, voltage of the resistor unit whose resistance value has been changed in the first state, the first resistance value, the second resistance value, the third resistance value, and the changed resistance value.

4. The resistance measurement device of claim 1, wherein the processing unit compares the insulation resistance with a reference insulation resistance to determine whether the insulation resistance is within a normal range.

5. The resistance measurement device of claim 1, wherein the insulation resistance is a total parallel insulation resistance of the first channel and the second channel.

6. The resistance measurement device of claim 1, wherein the first resistor unit comprises a first resistor, a second resistor connected in parallel to the first resistor, and a first switch connected in series to the second resistor,
the second resistor unit comprises a third resistor, a fourth resistor connected in parallel to the third resistor, and a second switch connected in series to the fourth resistor, and
the third resistor unit comprises a fifth resistor, a sixth resistor connected in parallel to the fifth resistor, and a third switch connected in series to the sixth resistor.

7. The resistance measurement device of claim 6, wherein the second resistor, the fourth resistor, and the sixth resistor have a same resistance value.

8. The resistance measurement device of claim 1, comprising:
a fourth switch configured to connect the first resistor unit, the second resistor unit, and the third resistor unit to ground.

9. A resistance measurement circuit comprising:
a plurality of (+) terminal resistor units connected between a (+) terminal of each of a plurality of channels and ground;
one (−) terminal resistor unit connected between a node to which (−) terminals of the plurality of channels are connected and the ground; and
a voltage measurement unit configured to measure a voltage applied across both ends of at least one (+) terminal resistor unit of the plurality of (+) terminal resistor units, or the (−) terminal resistor unit,
wherein the plurality of channels are connected in parallel.

10. The resistance measurement circuit of claim 9, comprising:
a processing unit configured to calculate a total parallel insulation resistance of the plurality of channels by using resistance value of each of the plurality of (+) terminal resistor units, resistance value of the (−) terminal resistor unit, and one of the voltage values of the at least one (+) terminal resistor unit and the (−) terminal resistor unit.

11. The resistance measurement circuit of claim 10, wherein the processing unit is configured to:
change a resistance value of a resistor unit having a largest voltage across both ends measured in a first state; and
calculate a total parallel insulation resistance by using a voltage difference measured in a second state where the resistance value is changed, voltage of the resistor unit whose resistance value is changed in the first state, resistance value of each of the plurality of (+) terminal resistor units in the first state, resistance value of the (−) terminal resistor unit in the first state, and the changed resistance value.

12. The resistance measurement circuit of claim 10, wherein the plurality of (+) terminal resistor units comprises a first resistor unit connected between a (+) terminal of a first channel and ground and a second resistor unit connected between a (+) terminal of a second channel and the ground, and
the (−) terminal resistor unit comprises a third resistor unit connected between a (−) terminal of the first channel, a (−) terminal of the second channel, and the ground.

13. The resistance measurement circuit of claim 1, wherein the processing unit compares the total parallel insulation with a reference insulation resistance to determine whether the total parallel insulation resistance is within a normal range.

14. The resistance measurement circuit of claim 12, wherein the first resistor unit comprises a first resistor, a second resistor connected in parallel to the first resistor, and a first switch connected in series to the second resistor,
the second resistor unit comprises a third resistor, a fourth resistor connected in parallel to the third resistor, and a second switch connected in series to the fourth resistor, and
the third resistor unit comprises a fifth resistor, a sixth resistor connected in parallel to the fifth resistor, and a third switch connected in series to the sixth resistor.

15. The resistance measurement circuit of claim 13, wherein the second resistor, the fourth resistor, and the sixth resistor have a same resistance value.

16. The resistance measurement circuit of claim 12, comprising:
a fourth switch configured to connect the first resistor unit, the second resistor unit, and the third resistor unit to the ground.

17. A resistance measuring method, comprising:
turning on a switch that connects a resistance measurement circuit connected to a plurality of channels connected in parallel to ground;
measuring a voltage between a (+) terminal of each of the plurality of channels and the ground and a voltage between a node to which (−) terminals of the plurality of channels are connected and the ground in a first state;
changing a resistance value of one of a plurality of (+) terminal resistor units between the (+) terminals of the plurality of channels and the ground and one (−) terminal resistor unit between a node to which the (−) terminals of the plurality of channels are connected and the ground; and
calculating a total parallel insulation resistance of the plurality of channels by using resistance value of each of the plurality of (+) terminal resistor units, resistance value of the (−) terminal resistor unit, and voltage value of one of voltage values of at least one (+) terminal resistor unit and the (−) terminal resistor unit.

18. The resistance measuring method of claim 17, wherein the changing of the resistance value comprises:
changing the resistance value by connecting a resistor having a preset resistance value in parallel to the resistor unit having the largest magnitude of the voltage measured at both ends in the first state.

19. The resistance measuring method of claim 17, wherein the calculating of the total parallel insulation resistance of the plurality of channels comprises:
calculating the total parallel insulation resistance by using the voltage value in the second state where the resistance value of the resistor unit whose resistance value has been changed is changed, the resistance value of the resistor unit whose resistance value has been changed in the first state, the resistance value of each of the plurality of (+) terminal resistor units in the first state, the resistance value of the (−) terminal resistor unit in the first state, and the resistance value of the resistors connected in parallel.

20. The resistance measuring method of claim 17, comprising:
comparing the total parallel insulation resistance with the reference insulation resistance to determine whether the total parallel insulation resistance is within a normal range.
